(19) United States
(12) Patent Application Publication
(10) Pub. No.: US 2006/0214203 A1
(43) Pub. Date: Sep. 28, 2006

(54) Formation of micro lens by using flowable oxide deposition

(76) Inventors: Jin Li, Boise, ID (US); Li Li, Boise, ID (US)

Correspondence Address: DICKSTEIN SHAPIRO LLP, 1825 EYE STREET NW, Washington, DC, 20006-5403, US

(21) Appl. No.: 11/442,204

(22) Filed: May 30, 2006

Related U.S. Application Data
(62) Division of application No. 11/072,452, filed on Mar. 7, 2005.

(51) Int. Cl. H01L 31/062

(52) U.S. Cl. 257/294; 438/70; 359/619; 257/E27.133

(57) ABSTRACT

A method of forming a microlens employing relatively few processing steps and with a controlled microlens radii using a processes including a flowable oxide is disclosed. A lens form having recesses therein is produced and a flowable oxide material is deposited in recesses. Surface tension of the flowable oxide material within the form recesses creates spherical dips within the oxide material. The flowable oxide is then converted into silicon oxide by a heat process. A microlens material is deposited over the silicon oxide having spherical dips, and planarized to form a focus microlens array.

### FIELD OF THE INVENTION

The present invention relates to the field of semiconductor imaging devices and, in particular, to semiconductor imager microlenses.

### BACKGROUND OF THE INVENTION

Imaging devices, including charge coupled devices (CCD) and complementary metal oxide semiconductor (CMOS) sensors, among others, have commonly been used in photo-imaging applications.

Exemplary CMOS imaging circuits, processing steps thereof, and detailed descriptions of the functions of various CMOS elements of an imaging circuit are described, for example, in U.S. Pat. No. 6,140,630 to Rhodes, U.S. Pat. No. 6,376,868 to Rhodes, U.S. Pat. No. 6,310,366 to Rhodes et al., U.S. Pat. No. 6,326,652 to Rhodes, U.S. Pat. No. 6,204,524 to Rhodes, U.S. Pat. No. 6,333,205 to Rhodes, and U.S. patent application Ser. No. 10/653,222 to Li. The disclosures of each of the forgoing patents are hereby incorporated by reference in their entirety.

Conventional methods of forming microlenses for solid state imagers typically either include a step of etching a precursor material using a chemical etching or reactive ion etching which is difficult to control, or includes several more processing steps of, for example, etching recesses in an interlayer dielectric over the imaging circuitry, depositing a lens-forming layer in the etched recesses and over the interlayer dielectric layer, depositing a photoresist layer over the lens-forming layer, patterning the photoresist to expose the lens-forming layer around the perimeter of the etched recesses, etching the lens-forming layer such that it is thicker in the areas over the etched recesses, and treating the lens-forming layer to form refractive lenses.

A simpler method of forming microlens structures would be beneficial.

### BRIEF SUMMARY OF THE INVENTION

In disclosed exemplary embodiments, the present invention provides a method of forming an imager microlens employing relatively few processing steps and with a controlled microlens radii using a process including a flowable oxide. A lens form having recesses therein is produced and a flowable oxide material is deposited in the recesses. Surface tension of the flowable oxide material within the form recesses creates spherical dips within the oxide material. The flowable oxide is then converted into silicon oxide by a heat process. A microlens material is deposited over the silicon oxide having spherical dips, and planarized to form a focus microlens array.

The foregoing and other features of the invention will be more readily apparent from the following detailed description of exemplary embodiments of the invention, which are provided in conjunction with the accompanying drawings.

### BRIEF DESCRIPTION OF THE DRAWINGS

FIG. 1 is a block diagram of a CMOS imager system;

FIG. 2 is a cross-sectional view of an imaging device having an array of pixel cells and microlenses according to an embodiment of the present invention;

FIG. 3 is a cross-sectional view of a microlens array according to one embodiment of the present invention;

FIG. 4 is a cross-sectional view of a microlens array according to another embodiment of the present invention;

FIG. 5 is a cross-sectional view of a semiconductor wafer undergoing the process of a preferred embodiment of the present invention;

FIG. 6 is an isometric view of a semiconductor wafer corresponding to the cross-sectional view of FIG. 5;

FIG. 7 shows the wafer of FIG. 5 at a processing step subsequent to that shown in FIG. 5;

FIG. 8 is an isometric view of a semiconductor wafer corresponding to the cross-sectional view of FIG. 7;

FIG. 9 shows the wafer of FIG. 7 at a processing step subsequent to that shown in FIG. 7;

FIG. 10 shows the wafer of FIG. 9 at a processing step subsequent to that shown in FIG. 9; and

FIG. 11 is an illustration of a processing system having an imager with a microlens array according to the present invention.

### DETAILED DESCRIPTION OF THE INVENTION

In the following detailed description, reference is made to the accompanying drawings which form a part hereof, and in which is shown by way of illustration specific embodiments in which the invention may be practiced. These embodiments are described in sufficient detail to enable those skilled in the art to practice the invention, and it is to be understood that other embodiments may be utilized, and that structural, logical and electrical changes may be made without departing from the spirit and scope of the present invention.

The term “substrate” is to be understood as a semiconductor-based material including silicon, silicon-on-insulator (SOI) or silicon-on-sapphire (SOS) technology, doped and undoped semiconductors, epitaxial layers of silicon supported by a base semiconductor foundation, and other semiconductor structures. Furthermore, when reference is made to a “substrate” in the following description, previous process steps may have been utilized to form regions or junctions in or over the base semiconductor structure or foundation. In addition, the semiconductor need not be silicon-based, but could be based on silicon-germanium, germanium, or gallium arsenide.

The term “pixel” refers to a picture element unit cell containing a photosensor and other structures for converting light radiation to an electrical signal. For purposes of illustration, a representative pixel is illustrated in the figures and description herein and, typically, fabrication of all pixels in an imager will proceed simultaneously in a similar fashion.

Although the exemplary embodiments of the invention are shown as being fabricated in conjunction with a CMOS imager, the invention is not so limited and can be used with any type of imager or display device requiring a microlens structure. The following detailed description is, therefore, not to be taken in a limiting sense, and the scope of the present invention is defined by the appended claims.

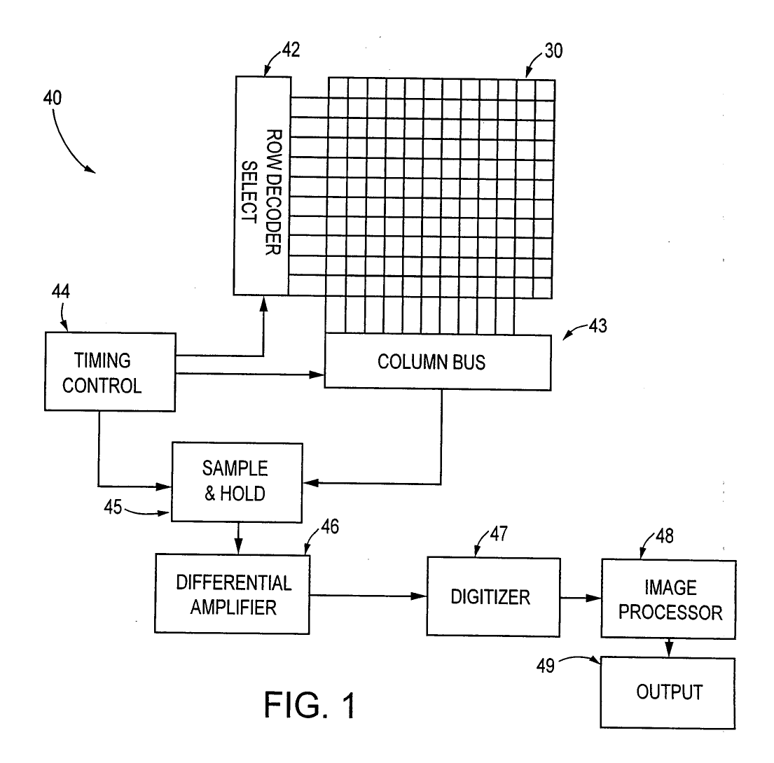

Referring now to the drawings, where like elements are designated by like reference numerals, FIG. 1 shows a portion of a CMOS imager system 40 with an imaging device 30 having a pixel array connected to a row decode/selector 42 and column bus 43, which are operated by timing and control circuit 44. The pixel array of the imaging device 30 converts an incident light image into pixel image signals which are used to form an electronic representation of the incident image. The pixels of device 30 are read out row by row and each pixel of the array provides its signals through a column bus 43. The signals include a reset signal Vrst and an image signal Vsig and are sent to a sample and hold circuit 45, also operated by timing and control circuit 44. The sample and hold circuit 45 acquires the Vrst and Vsig signals for each pixel and sends them to a differential amplifier 46 which subtracts them (Vrst−Vsig) to form a pixel output signal for each pixel representing incident light. The pixel signals are then sent to a digitizer 47, image processor 48 and ultimately are provided at an output line 49 as a digitized image signal.

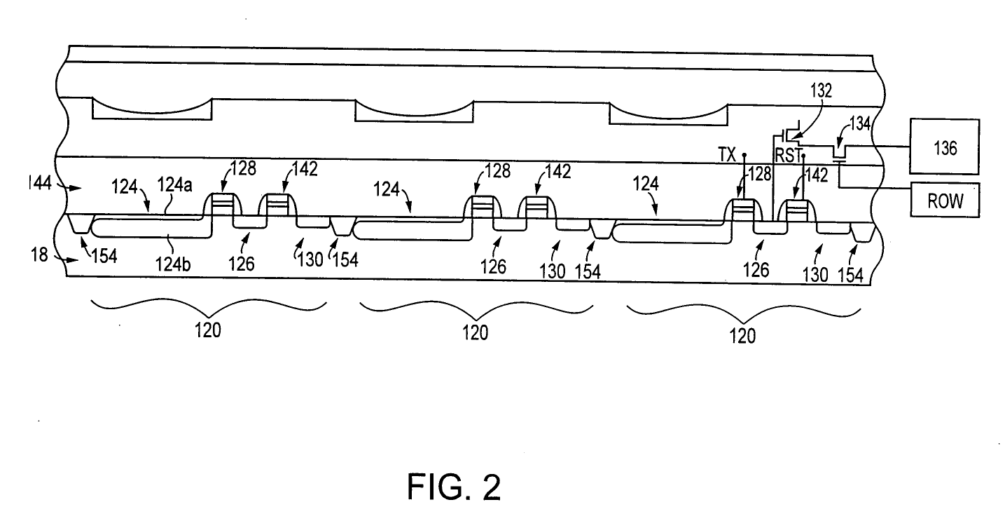

FIG. 2 is a partial cross-section through three pixels of the imaging device 30 pixel array; imaging device 30 includes an array of microlenses 112 provided over a cooresponding array of pixel cells 120. Each of pixel cells 120 includes a photosensor 124. Photosensor 124 may be any photosensitive region including a photodiode, a photogate, or the like, and the invention is not limited to the illustrated pixel cell 120. Each pixel cell 120 may be formed in or at a surface of a substrate 118. Each pixel cell 120 may be a four-transistor (4T) pixel cell. It should be noted that this illustration is not intended to limit the invention to a CMOS imager or to a particular pixel cell configuration, as the pixel cell may contain three, four, five, or more transistors, or could be implemented as a passive pixel without transistors.

The individual microlenses of array 112 operate to refract incident light radiation onto a respective photosensor 124. The photosensor 124 is illustrated in FIG. 2 as a photodiode which has a p+region 124a and an n-type region 124b. When incident light contacts the illustrated photosensor 124, electrons accumulate in the n-type region 124b. The electrons are then transferred to a charge storage region (or floating diffusion region) 126 when the transfer gate 128 is activated by a TX signal. When row select transistor 134 is turned on by the ROW signal, source follower transistor 132, which has a gate connected to charge storage region 126, provides an output signal representing the transferred charge stored in storage region 126. Reset gate 142 can be activated by signal RST to reset storage region 126. The source follower transistor 132 also provides an output reset signal when row select transistor 134 is on while or after storage region 126 is reset. It should be noted that the pixel cells 120 source follower transistor 132, row select transistor 134, and readout circuitry 136 are omitted from subsequent drawings for the sake of clarity.

It should also be noted that the imaging device 30 as depicted in FIG. 2 may include additional layers. For example, additional processing steps may be used to form insulating, shielding, and metallization layers to connect gate lines and other connections to the pixel sensor cells. Also, additional passivation layers may be formed under the metallization layers. For the sake of clarity, all of these potential insulation, shielding, metallization and passivation layers are represented as layer 144 in FIG. 2.

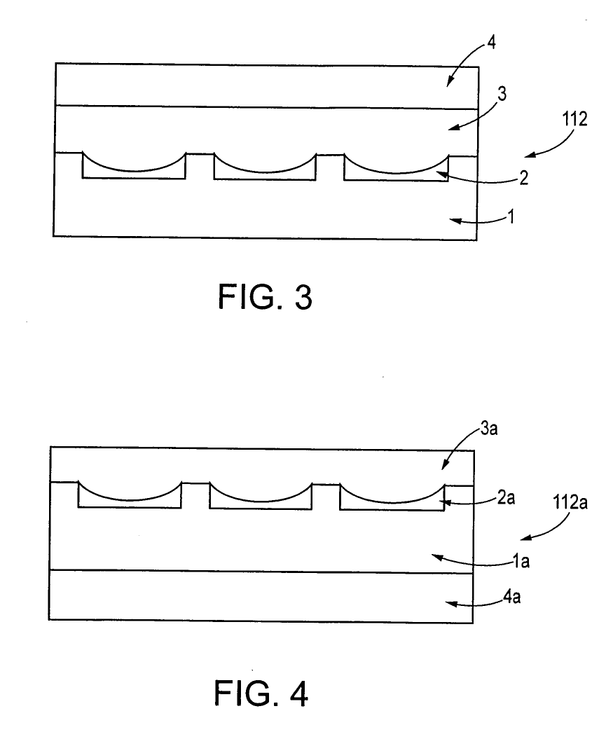

FIG. 3 shows an embodiment of the present invention. The microlens array 112 comprises a form 1, a lens-shaping layer 2 comprising an array of layers seated within the form 1, a lens layer 3 over the form 1 and lens-shaping layer 2, and a color filter layer 4 provided over the lens layer 3.

FIG. 4 shows another embodiment of the present invention. The microlens array 112a is provided with the color filter layer 4a formed over the pixel array (not shown), such that the form 1a, lens-shaping layer 2a, and lens layer 3a are provided over the color filter layer 4a. The embodiment shown in FIG. 4 may be employed if the subsequent processing steps (described below) are performed at temperatures of less than about 250° C., due to the degradable nature of the materials used for color filters when exposed to temperatures above about 250° C.

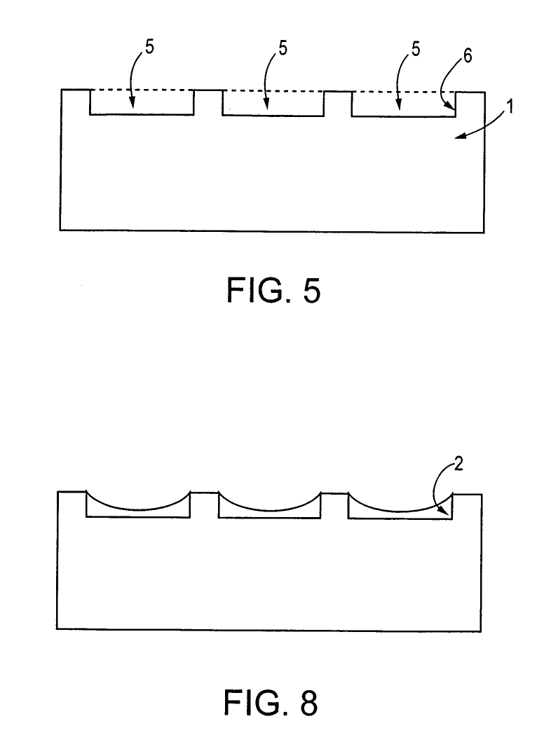

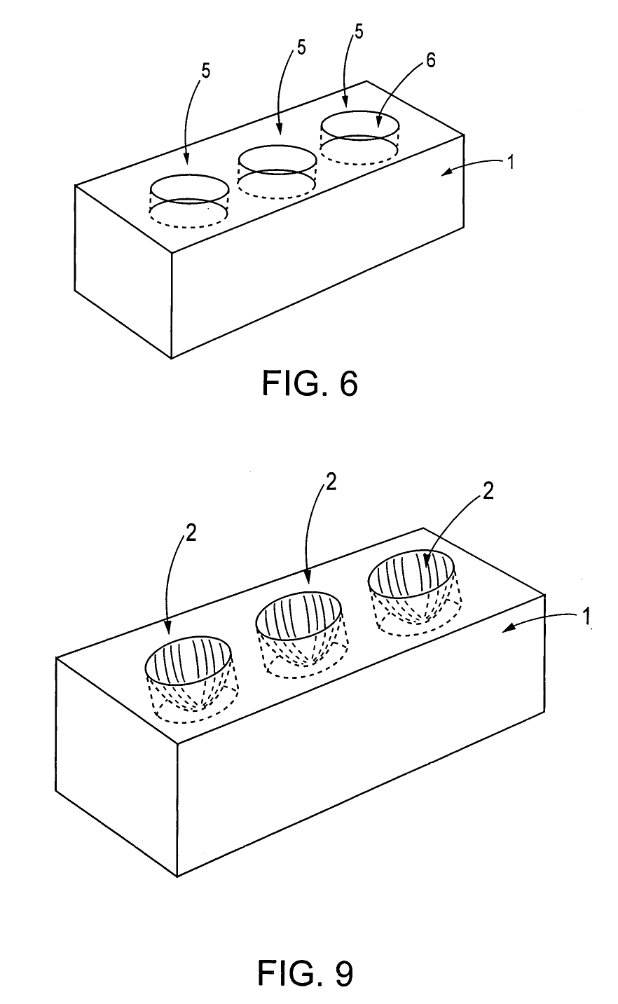

FIG. 5 illustrates a cross-section of a form 1 having recesses 5 in the top surface of the form 1. FIG. 6 is a corresponding isometric illustrations of the recesses 5. The form 1 comprises a material such as an interlayer dielectric material or TEOS, chosen for its light transmissivity and low index of refraction. As one example, form 1 has an index of refraction of less than approximately 1.6. Form 1 is fabricated by a typical processes (not shown) including depositing the form material, patterning over the form material with a photoresist, and etching to form the recesses 5. When the remaining photoresist is removed, the form 1 having recesses 5 results.

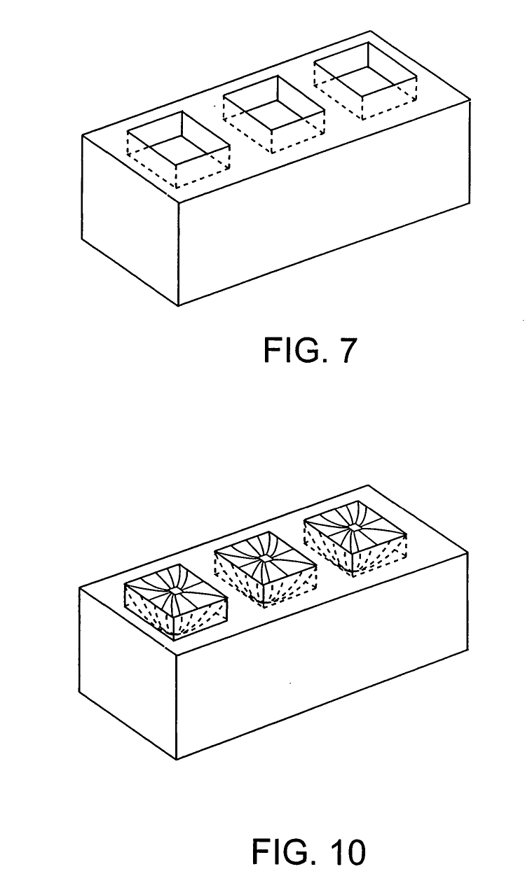

The recesses 5 are of cylindrical shape, having an inner surface 6 with substantially vertical sidewalls and a horizontal bottom. However, other recess shapes could be used. For example, a square recess may be used as shown in isometric view in FIG. 7. The diameter, or width, and depth of the cylindrical recesses is determined by the choice of etchant and etching parameters, the choice of subsequent flowable oxide material (to be discussed in greater detail later), the viscosity of this flowable oxide material, and deposition processing parameters of the flowable oxide material such as deposition temperature, pressure, and choice of carrier gas.

A flowable oxide material is next deposited on the inner surfaces 6 of the cylindrical recesses 5 to form an array of layers, to be referred collectively as lens-shaping layer 2, as shown in the cross-section of FIG. 8. FIG. 9 is a corresponding isometric illustration of the recesses 5 having the lens-shaping layer 2 deposited therein. FIG. 10 is an isometric illustration of square recesses having a lens-shaping layer deposited therein. The flowable oxide material may be deposited by methods such as chemical vapor deposition (CVD). The flowable oxide material has a viscosity which causes it to adhere to the inner surfaces 6 of the cylindrical recesses 5 by surface tension. Due to the meniscus characteristic of the flowable oxide material, the top surface of the lens-shaping layer 2 has a spherical concave shape. The shape desired for the purposes of directing incident light to a photocapacitor in the underlying circuitry of the imaging device can be modified by changing the flowable oxide material or its viscosity, by adjusting deposition parameters such as temperature, pressure, and carrier gas, in addition to dimensions of the cylindrical recesses 5, as discussed above.

In one exemplary process, deposition is performed at a pressure of about 300 Torr and a temperature in a range of about 20°-500° C., preferably at about 125° C., using a precursor gas such as trimethyl silane (TMS) flowed at a rate in the range of about 1 to 10,000 sccm, preferably about 175 sccm, oxygen gas flowed at a rate in the range of about 1 to 10,000 sccm, preferably about 2000 sccm, where approximately 15 to 20% of the oxygen gas is ozone, and an inert gas such as helium, argon, or other inert gas as a carrier gas, flowed at a rate of about 800 sccm, for about 1 to 600 seconds, or about 60 seconds as required to obtain a lens-shaping layer 2 of desired thickness. The TMS, chosen for its volatility and flowable methyl properties, reacts with the ozone to create a flowable oxide material having the desired viscosity. Any carbon reside resulting from the TMS-ozone reaction may be removed by flowing pure O₂ plasma over the structure at a high temperature in the range of about 20° to about 1100° C., preferably about 125° C.

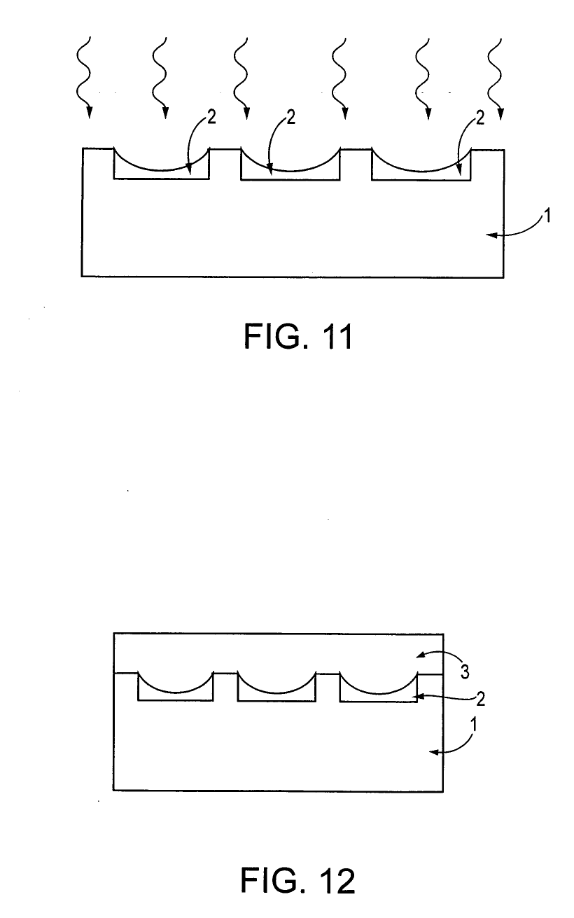

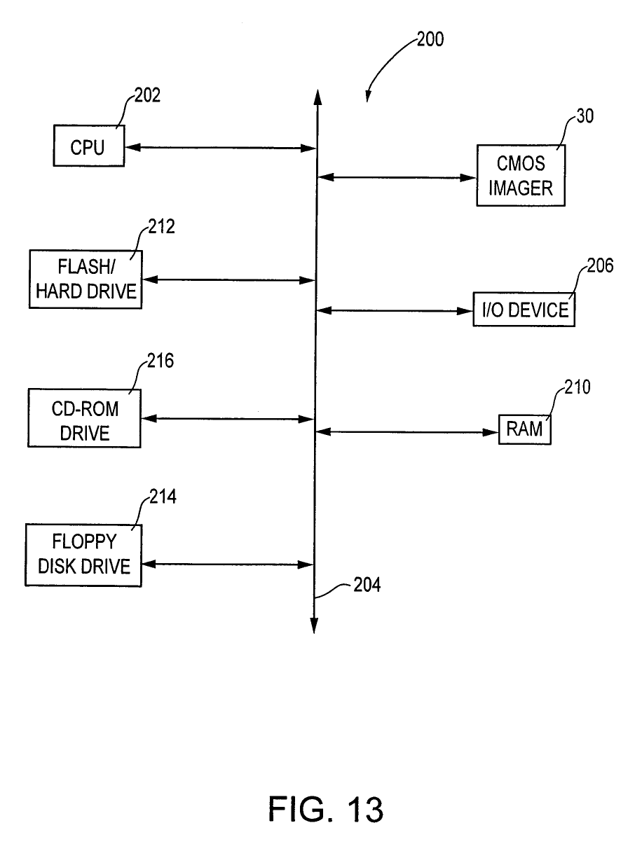

FIG. 11 shows a subsequent processing step, wherein the lens-shaping layer 2 is treated by a heat treatment process using a temperature of about 200° C., which converts the flowable oxide material to a silicon oxide. The flowable oxide material is chosen for its light transmissivity and low index of refraction after its conversion to the silicon oxide material. The final silicon oxide material has an index of refraction that is approximately the same as that of the form 1.

A lens layer 3 is next deposited over the lens-shaping layer 2 and form 1, as shown in FIG. 12. The lens layer 3 has an index of refraction greater than the index of refraction of the lens-shaping layer 2 and form 1. The lens layer 3 may be a silicon nitride having an index of refraction of about 2.0, tantalum oxide (Ta₂O₅) having an index of refraction of about 2.2, or any other glass having a high index of refraction, typically an index of refraction of greater than that of the form 1 or the lens-shaping layer 2. The lens layer 3 is then planarized by chemical mechanical polishing (CMP) or other method of planarization. A color filter layer 4 may be formed over the lens layer 3 to obtain the embodiment illustrated in FIG. 3.

Alternatively, if the processes described above are performed at temperatures below about 250° C., then a color filter layer 4a may be formed directly over the pixel and any insulating, shielding, metallization, and passivation layers, such that the form 1a, lens-shaping layer 2a, and lens layer 3a may be formed over the color filter layer 4a, as illustrated in FIG. 4.

Pixels using microlenses of the present invention can be used in a pixel array of the imager device 30 illustrated in FIG. 1. FIG. 13 shows a processing system 200 which includes an imager device 30 as in FIG. 1 employing microlenses fabricated in accordance with the present invention. The imager device 30 may also receive control or other data from system 200 as well. Examples of processor systems, which may employ the imager device 30, include, without limitation, computer systems, camera systems, scanners, machine vision systems, vehicle navigation systems, video telephones, surveillance systems, auto focus systems, star tracker systems, motion detection systems, image stabilization systems, and other imaging systems.

System 200 includes a central processing unit (CPU) 202 that communicates with various devices over a bus 204. Some of the devices connected to the bus 204 provide communication into and out of the system 200, illustratively including an input/output (I/O) device 206 and imager device 30. Other devices connected to the bus 204 provide memory, illustratively including a random access memory system (RAM) 210, FLASH memory or hard drive 212, and one or more peripheral memory devices such as a floppy disk drive 214 and compact disk read-only-memory (CD-ROM) drive 216. Any of the memory devices, such as the FLASH memory or hard drive 212, floppy disk drive 214, and CD-ROM drive 216 may be removable. The imager 30 may be combined with a processor, such as a CPU, digital signal processor, or microprocessor, in a single integrated circuit. The imager 30 may be a CCD imager, a CMOS imager, or any other type of imager. Also, although the microlenses have been described as being fabricated for imagers, the invention may also be used to fabricate microlenses for display devices.

The above description and drawings are only to be considered illustrative of exemplary embodiments which achieve the features and advantages of the invention. Modification of, and substitutions to, specific process conditions and structures can be made without departing from the spirit and scope of the invention. Accordingly, the invention is not to be considered as being limited by the foregoing description and drawings, but is only limited by the scope of the appended claims.

1-10. (canceled)

11. A method of forming a microlens, said method comprising:
forming a light transmissive layer comprising a solidified flowable oxide having a planar bottom surface and a planar top surface;
forming a recess in said light transmissive layer;
depositing a flowable oxide material in a bottom and on a sidewall of said cylindrical recess;
transforming said flowable oxide into a light transmissive solid silicon oxide material; and
depositing a lens material over said light transmissive solid silicon oxide material and said light transmissive layer.

12. The method of claim 11, wherein said recess has one of a circular cylindrical shape and a square cylindrical shape.

13. The method of claim 11, wherein said step of transforming said flowable oxide in said solid silicon oxide material comprises a heat treatment step.

14. The method of claim 13, further comprising planarizing said lens material and depositing a color filter material over said lens material.

15. The method of claim 14, wherein said heat treatment step is conducted at temperatures greater than about 250° C.

16. The method of claim 13, further comprising forming a color filter material over a substrate before providing said light transmissive material.

17. The method of claim 16, wherein said heat treatment step is conducted at temperatures less than 250° C.

18. A method of forming a pixel cell of an imaging device, said method comprising:
providing a pixel circuit in a semiconductor wafer, said pixel circuit having a photosensor;
providing a light-transmissive form having a recess over said photosensor;
forming a flowable oxide within said recess of said first light transmissive form;
solidifying said flowable oxide; and
forming a lens layer over said first transmissive form and said flowable oxide.

19. The method of claim 18, wherein said recesses have one of a circular cylindrical shape and a square cylindrical shape.

20. The method of claim 18, wherein said flowable oxide is formed with a top surface having a concave spherical shape.

21. The method of claim 20, wherein said concave spherical shape directs incident light toward said light-capturing region of said pixel circuit.

22. The method of claim 18, wherein said step of forming flowable oxide within said recess comprises depositing a flowable oxide material on a sidewall and a bottom of said recess.

23. The method of claim 22, wherein said step of solidifying said flowable oxide comprises heating said wafer at a temperature greater than about 125° C.

24. The method of claim 23, further comprising depositing a color filter layer over said lens layer.

25. The method of claim 22, wherein said step of heating is performed at a temperature less than about 125° C.

26. The method of claim 25, further comprising forming a color filter layer over said semiconductor wafer prior to forming said light-transmissive form.
